(19) United States
(12) Patent Application Publication
(10) Pub. No.: US 2019/0198643 A1
(43) Pub. Date: Jun. 27, 2019

(54) VERTICAL CHANNEL DEVICE AND METHOD OF FORMING SAME

(71) Applicant: IMEC vzw, Leuven (BE)

(72) Inventors: Boon Teik Chan, Leuven (BE); Anabela Veloso, Leuven (BE); Efrain Altamirano Sanchez, Kessel-Lo (BE); Zheng Tao, Heverlee (BE)

(21) Appl. No.: 16/220,361

(22) Filed: Dec. 14, 2018

(30) Foreign Application Priority Data
Dec. 22, 2017 (EP) 17210286.5

(51) Int. Cl. H01L 29/66; H01L 29/08; H01L 29/78; H01L 21/3065

(52) U.S. Cl. CPC H01L 29/66666; H01L 29/0847; H01L 29/42372; H01L 29/6653; H01L 21/3065; H01L 29/7827

(57) ABSTRACT

The disclosed technology generally relates to semiconductor devices and more particularly to a vertical channel device and a method of fabricating the same. According to one aspect, a method for fabricating a vertical channel device includes forming a vertical semiconductor structure including an upper portion, an intermediate portion and a lower portion, by etching a semiconductor layer stack arranged on a substrate. The semiconductor layer stack includes an upper semiconductor layer, an intermediate semiconductor layer and a lower semiconductor layer, wherein the intermediate semiconductor layer is formed of a material different from a material of the lower semiconductor layer and different from a material of the upper semiconductor layer. Forming the vertical semiconductor structure includes: etching the upper semiconductor layer to form the upper portion and the intermediate semiconductor layer to form the intermediate portion, detecting whether the etching has reached the lower semiconductor layer, and in response to detecting that the etching has reached the lower semiconductor layer, changing to a modified etching chemistry being different from an etching chemistry used during the etching of the intermediate semiconductor layer, and etching the lower semiconductor layer using the modified etching chemistry to form the lower portion. The modified etching chemistry is such that the lower portion is formed to present, along at least a part of the lower portion, a lateral dimension gradually increasing along a direction towards the substrate. The method further comprises forming a gate stack extending vertically along the intermediate portion to define a channel region of the vertical channel device.

### CROSS-REFERENCE TO RELATED APPLICATIONS

This application claims foreign priority to European Patent Application No. EP 17210286.5, filed Dec. 22, 2017, the content of which is incorporated by reference herein in its entirety.

### BACKGROUND

### Field

The disclosed technology generally relates to semiconductor devices and more particularly to a vertical channel device and a method of fabricating the same.

### Description of the Related Technology

Driven by the desire to produce even more power-efficient semiconductor devices and area-efficient circuit designs, new semiconductor devices are being developed. One promising type of devices is vertical channel transistor devices. Because the vertical channel transistor devices have device regions that extend or are arranged in a vertical direction, e.g., orthogonal to the substrate surface, the overall device footprint can be scaled more effectively. For example, a vertical channel transistor device may include a vertically oriented semiconductor structure and a gate extending vertically along the semiconductor structure. One example of a vertical channel transistor device is referred to in the relevant industry as the vertical gate-all-around field effect transistor (GAAFET). Providing a vertical channel device with good electrostatic properties and at the same time a low series resistance is, however, challenging.

### SUMMARY OF CERTAIN INVENTIVE ASPECTS

An objective of the disclosed technology is to address these and other challenges in scaling vertical channel transistor. Further or alternative objectives may be understood from the following.

According to an aspect of the disclosed technology, a method of forming a vertical channel device comprises forming a vertical semiconductor structure including an upper portion, an intermediate portion and a lower portion, by etching a semiconductor layer stack arranged on a substrate. The semiconductor layer stack includes an upper semiconductor layer, an intermediate semiconductor layer and a lower semiconductor layer. The intermediate semiconductor layer is formed of a material different from a material of the lower semiconductor layer and different from a material of the upper semiconductor layer. The method of forming the vertical semiconductor structure comprises etching the upper semiconductor layer to form the upper portion and etching the intermediate semiconductor layer to form the intermediate portion. The method additionally comprises detecting whether the etching has reached the lower semiconductor layer, and in response to detecting that the etching has reached the lower semiconductor layer, changing to a modified etching chemistry that is different from an etching chemistry used during the etching of the intermediate semiconductor layer, and etching the lower semiconductor layer using the modified etching chemistry to form the lower portion. The modified etching chemistry is such that the lower portion has, along at least a part of the lower portion, a lateral dimension that gradually increases along a direction towards the substrate. The method further comprises forming a gate stack extending vertically along the intermediate portion to define a channel region of the vertical channel device.

The disclosed method enables forming of a vertical channel device having good electrostatic properties and at the same time a low series resistance. As realized by the inventors, conventional methods of forming a vertical channel device with a thin channel (e.g., a channel of a small lateral dimension or small horizontal cross-section) can result in a thin lower portion (which can include, e.g., a source or drain of the vertical channel device) as well. This may have an adverse impact on the series resistance of the device due to a reduced contact area towards an underlying connection region such as a bottom electrode region. Meanwhile, forming a vertical channel device with a wider lower portion, e.g., a wider (e.g., having a greater lateral dimension) source/drain portion can result in a wide channel portion as well, which may have an adverse impact on the electrostatics of the device. The disclosed fabrication method provides control over a profile during the etching of the layer stack such that a vertical semiconductor structure may be formed with an intermediate portion with a targeted (advantageously small) lateral dimension and a lower portion with an increasing lateral dimension along a downward direction (a “tapering” along an upward direction), and thus providing an increased contact area.

Furthermore, detecting whether the etching of the intermediate layer has reached the lower layer enables an advantageous degree of control of determining when to change to the modified etching chemistry. Thus, modified etching chemistry may be selectively applied to the lower layer and the lower portion.

The detection of when the etching has reached the lower layer may be performed by a suitable technique such as optical emission spectroscopy during the etching.

As used herein, the term vertical (e.g., with reference to an extension, a direction or a plane) denotes an extension/direction/plane being parallel to a vertical geometrical axis extending perpendicular to the substrate (e.g., perpendicular to a main plane of extension or main surface of the substrate). The terms above, upper, top and below, lower, bottom may accordingly be used to refer to relative positions along the vertical axis. The terms downward and upward may be used to refer to vertical directions towards and away from, respectively, the main surface of the substrate. The term horizontal may correspondingly denote a direction/extension/plane being perpendicular to the vertical geometrical axis.

The term lateral dimension (e.g., of a feature such as the lower portion) denotes a dimension along a direction perpendicular to the vertical geometrical axis (i.e. along a horizontal direction).

A lower portion is formed to present, along at least a part of the lower portion, a lateral dimension, e.g., a width, that gradually increases along a direction towards the substrate. More specifically, the lower portion may be formed to present, along at least a part of the lower portion, an increasing cross-sectional area along the direction towards the substrate. Thereby, a bottom portion of the lower portion may present a greater cross-sectional area than a top portion of the lower portion.

As used herein, a vertical channel device refers to a device or a semiconductor device, e.g., a transistor, having one or more features such as a channel that are oriented vertically with respect to a major surface of the substrate.

As used herein an orientation of the channel of a device refers to the direction of the flow of charge of carriers, e.g., direction of the net direction of charge of electrons or holes through the channel, during use of the device. The transistor may advantageously be a field-effect transistor (FET).

According to one embodiment, the aforementioned etching chemistries are dry etching chemistries each including a fluoride-including component and a carbon-including component, wherein a fluoride-to-carbon-ratio in the modified etching chemistry is smaller than a fluoride-to-carbon-ratio in the etching chemistry used during the etching of the intermediate semiconductor layer.

As described herein, a fluoride-including component refers to a compound that includes a fluoride that is not carbon based. For example, while a fluoride-including component may include a sulfur hexafluoride (SF₆). However, a fluoride-including component does not include carbon tetrafluoride (CF₄).

Dry etching chemistries allow anisotropic etching of the semiconductor layer stack in the vertical direction. A high-aspect ratio vertical semiconductor structure may thus be formed. Moreover, as realized by the inventors, having a modified etch chemistry with a fluoride-to-carbon-ratio which is smaller than that of the etching chemistry used during the etching of the intermediate layer, enables forming of the lower portion with a tapering. This may be attributed to a lower relative amount of fluoride compared to carbon during etching of the lower layer resulting in a more efficient surface passivation of sidewalls during etching with respect to fluoride-etchants (e.g., a thicker passivation layer may form on the sidewall of the pillar being formed). The passivation may in turn result in a tapering during the etching.

Hence, a fluoride-to-carbon ratio during the etching of the lower layer may be controlled such that the gradually increasing lateral dimension is obtained for the lower portion.

For at least one of the etching chemistries, the fluoride-including component may advantageously include or be SF₆ and the carbon-including component may be a fluorocarbon (e.g., CₓF₂ₓ such as CF₄ or C₂F₄) or CHₓF_{y} (such as CH₂F₂). These compounds allow efficient etching of semiconductor layers, in particular Group IV semiconductors such as Si, Ge or SiGe, with control of the profile by controlling the ratios of the component gases. For example, using CFₓ or CHₓF_{y} as a component gas may result in formation of a polymerization layer on the etched sidewalls, which may counteract or reduce the fluoride-etch. Thus, the etching using relatively higher amounts of CFₓ or CHₓF_{y} may result in a relatively higher level of tapering.

The lower semiconductor layer may advantageously be etched with an etch chemistry where the ratio of SF₆ to CH₂F₂ is equal to or less than 1:1.2. This enables forming of a lower portion with a profile with a comparably uniform slope. Alternatively, the lower semiconductor layer may be etched with an etch chemistry where the ratio of SF₆ to CF₄ is equal to or less than 1:9. This also allows forming the lower portion to present a tapering.

The upper semiconductor layer may be etched with an etch chemistry where the ratio of SF₆ to CF₄ is in the range of 1:3 to 1:8, or greater than 1:3. Alternatively, upper semiconductor layer may be etched with an etch chemistry where the ratio of SF₆ to CH₂F₂ is in the range of 1:0.8 to 1:1.1, or greater than 1:0.8.

The intermediate semiconductor layer may be etched with an etch chemistry where the ratio of SF₆ to CF₄ is in the range of 1:3 to 1:8, or greater than 1:3. Alternatively, the intermediate semiconductor layer may be etched with an etch chemistry where the ratio of SF₆ to CH₂F₂ is in the range of 1:0.8 to 1:1.1, or greater than 1:0.8. Thereby, the upper portion and the intermediate portion may be formed to present a lateral dimension being more or less constant, or decreasing along a direction towards the substrate.

The upper semiconductor layer and the intermediate semiconductor layer may be etched using a same etching chemistry or different etching chemistries. By this the cross section of the upper portion and the intermediate portion can either be made with similar profile, by using the same etch chemistry, or different profiles, by using different etch chemistries.

According to one embodiment, a maximum lateral dimension of the intermediate portion is smaller than a maximum of the lateral dimension of the lower portion. This may contribute to improved electrostatics and a low series resistance.

According to one embodiment, the lower semiconductor layer has a greater Ge-content than the intermediate semiconductor layer.

Alternatively or additionally, the upper semiconductor layer may have a greater Ge-content than the intermediate semiconductor layer.

According to one embodiment, the lower semiconductor layer includes Si and Ge, the intermediate layer includes Si, and the upper semiconductor layer includes Si and Ge. A layer stack of these materials allows forming of a vertical semiconductor device with a Si-based channel and SiGe-based lower and upper source/drain portions. The lateral etch rate of these materials are sensitive to different ratios of fluoride to carbon in etching chemistries. This will allow for a lateral dimension of structures dry etched from these materials to be controlled by varying the ratio of fluoride to carbon.

According to one embodiment, one or both of the lower and the upper semiconductor layers have a higher Ge content relative to the middle semiconductor layer.

According to one embodiment, one or both of the lower and the upper semiconductor layers have a lower Si content relative to the middle semiconductor layer.

According to one embodiment, the upper portion and the lower portion are formed of SiGe and the intermediate portion is formed of Si.

By including these materials, a vertical semiconductor device can be made where a channel can be made from the intermediate layer and a source and a drain can be made from the upper and lower layers. The lateral dry etch rate of these materials are sensitive to the fluoride-to-carbon-ratio of the etching chemistry (e.g., different ratios of SF₆ to CH₂F₂ or SF₆ to CF₄).

According to one embodiment the method further comprises: subsequent to forming the upper portion, and prior to forming the intermediate portion, forming a spacer layer on sidewalls of the upper portion, and subsequent to forming the spacer layer, performing the etching of the intermediate semiconductor layer to form the intermediate portion.

The upper portion may thereby be masked from the etching chemistries used during etching of the intermediate portion. Hence, a risk of reducing a lateral dimension of the upper portion during etching of the intermediate portion may be mitigated. This in turn allows forming of the upper portion being wider than the intermediate portion. The spacer layer on the sidewalls of the upper portion may protect the upper portion both during the etching of the intermediate portion as well as during subsequent etching, such as during the etching of the lower portion.

The method may further comprise: subsequent to forming the intermediate portion, reducing a lateral dimension of the intermediate portion by etching the intermediate portion, wherein the spacer layer counteracts or masks to suppress or prevent etching of the upper portion. A selective thinning of the intermediate portion is thus allowed wherein the spacer layer on the sidewalls of the upper portion counteracts or masks to suppress or prevent a simultaneous thinning of the upper portion.

Alternatively or additionally, selective thinning of the intermediate portion may be achieved by: subsequent to forming the intermediate portion, reducing a lateral dimension of the intermediate portion by oxidizing the intermediate portion, wherein the spacer layer on the sidewalls of the upper portion counteracts oxidation of the upper portion.

The intermediate semiconductor layer may advantageously be formed of or comprise a material having a greater oxidation rate than a material the lower semiconductor layer (and optionally having a greater oxidation rate than a material forming the upper semiconductor layer) is formed or comprises. One such layer stack is a layer stack including a SiGe intermediate layer with a greater Ge content than the upper and the lower semiconductor layers, each of which may be a SiGe-layer or a Si-layer.

According to one embodiment, forming the gate stack includes forming a gate conductor enclosing the intermediate portion. A gate-all-around vertical channel device may thereby be formed.

According to another aspect of the disclosed technology a vertical channel device comprises a substrate on which a vertical semiconductor structure is arranged. The vertical channel device additionally includes an upper portion, an intermediate portion and a lower portion, wherein the intermediate portion is formed of a material different from a material of the lower portion and a material of the upper portion. The lower portion has, along at least a part of the lower portion, a lateral dimension that gradually increases along a direction towards the substrate, and a gate stack extending vertically along the intermediate portion to define a channel region of the vertical channel device.

A vertical channel device presenting good electrostatic properties and at the same time a low series resistance may thus be provided. The further advantages, details, embodiments and variations discussed in connection with the method aspect may apply correspondingly to the device aspect.

### BRIEF DESCRIPTION OF THE DRAWINGS

The above, as well as additional objects, features and advantages of the disclosed technology, will be better understood through the following illustrative and non-limiting detailed description, with reference to the appended drawings. In the drawings like reference numerals will be used for like elements unless stated otherwise.

FIGS. 1 to 5 illustrate intermediate structures at various stages of fabrication of a vertical channel device according to embodiments.

FIGS. 6 and 7 illustrate intermediate structures during fabrication of a a vertical channel device according to alternative embodiments.

### DETAILED DESCRIPTION OF CERTAIN ILLUSTRATIVE EMBODIMENTS

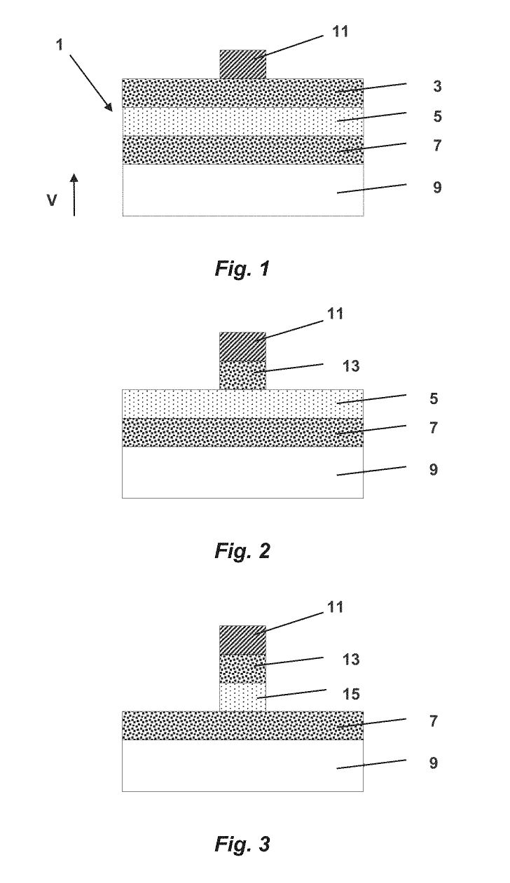

FIG. 1 illustrates a cross sectional view of an intermediate structure including a semiconductor layer stack 1 formed on a substrate 9. It will be appreciated that, while a portion of the intermediate is illustrated for clarity, the layer stack 1 and the substrate 9 may extend laterally or horizontally beyond the illustrated portion. It will also be appreciated that, while in the following, fabricating a single vertical channel device is described and illustrated for clarity, a plurality of such devices may be formed in parallel, e.g., simultaneously, or sequentially. It will further be appreciated that the relative dimensions of the shown elements, e.g., the relative thickness of the layers, may be schematic and may, for the purpose of illustrational clarity, differ from a physical structure.

The substrate 9 may be a semiconductor substrate, such as of a Group IV semiconductor material. The substrate 9 may, for instance, be a silicon (Si) substrate, a germanium (Ge) substrate or a silicon-germanium (SiGe) substrate. The substrate 9 may also have a multi-layered configuration, such as a silicon-on-insulator (SOI) substrate, a Ge on insulator (GeOI) substrate or a SiGeOI substrate.

The layer stack 1 includes, in a top-down direction (i.e., opposite to the vertical direction V indicated by an arrow in FIG. 1) an upper semiconductor layer 3, an intermediate semiconductor layer 5 and a lower semiconductor layer 7. The upper layer 3 is formed on the intermediate layer 5. The intermediate layer 5 is formed on the lower layer 7. The lower layer 7 is formed on a main surface of the substrate 9.

Each one of the layers 3, 5, 7 of the layer stack 1 may be formed of a different semiconductor material. At least the intermediate layer 5 may be formed of a material different from a material of the upper layer 3 and different from a material of the lower layer 7. In various embodiments, each one of the layers 3, 5, 7 may be a layer of a respective Group IV semiconductor (elemental or compound).

In some embodiments, the upper layer 3 and the lower layer 7 may each be a SiGe-layer with a Ge content in the range of 10% to 90% and the intermediate layer 5 may be a Si-including layer with a smaller Ge content than the upper layer 3 and the lower layer 7. By way of example, the upper layer 3 and the lower layer 7 may each have a Ge content of about 25% and the intermediate layer 5 may be a layer consisting of, or at least substantially consisting of, Si. However, embodiments are not so limited and in other embodiments, it is also possible to form the upper layer 3 and the lower layer 7 as layers Si- or SiGe-layers and the intermediate layer 5 as a SiGe-layer having a greater Ge-content than the upper layer 3 and the lower layer 7.

The layers 3, 5, 7 may be layers grown by a respective epitaxial process, for instance by chemical vapor deposition (CVD) or physical vapor deposition (PVD). Each one of the layer 3, 5, 7 may be formed with a respective thickness on the order of a few tens of nm. As non-limiting examples, a thickness of the upper layer 3 may be in the range of 40-70 nm, a thickness of the intermediate layer 5 may be in the range of 40-70 nm, and a thickness of the lower layer 7 may be in the range of 50-100 nm.

In various embodiments, the upper layer 3 and the lower layer 7 may each be doped with an n- or p-type dopant to allow forming of source/drain regions of the vertical channel device of the intended type. The intermediate layer 5 may be lightly doped by a dopant of an opposite type to that of the upper layer 3 and the lower layer 7, or be un-doped.

FIG. 1 illustrates an intermediate structure after a mask 11 is formed above the layer stack 1. The mask 11 may be formed on the upper layer 3. The mask 11 may be defined to have a suitable shape for forming the vertical channel transistor device, e.g., a circular or oval shape according to some embodiments, using which a pillar- or column-shaped vertical semiconductor structure with a corresponding cross-sectional shape may be formed. However, embodiments are not so limited and in some other embodiments, the mask 11 may also be defined with a rectangular or a suitable polygonal shape. The mask 11 may be a single-layer mask such as a resist-based mask, a carbon-based hard mask, an advanced patterning film (APF) or a multi-layered mask including a stack of sub-layers, such as a conventional lithographic layer stack. The mask 11 may defined in a single patterning process such as a single lithography-etch process, or using a multiple patterning process such as a multiple lithography-etch process (sometimes referred to as (litho-etch)^{x}, where x denotes the number of repeated lithography-etch processes).

FIGS. 2 through 4 illustrate intermediate structures at different stages of forming a vertical semiconductor structure including an upper portion 13, an intermediate portion 15 and a lower portion 17, by etching the layer stack 1. In FIG. 2, an upper portion 13 has been formed from the upper layer 3 by etching the upper layer 3 in regions outside of the upper layer 3 covered by the mask 11. In FIG. 3 an intermediate portion 15 has been formed from the intermediate layer 5 by etching the intermediate layer 5 in regions outside the intermediate layer 5 covered by the etch mask 11 (and by the upper portion 13). The intermediate portion 15 is formed directly below the upper portion 13. In other words, the intermediate portion 15 is vertically aligned with the upper portion 13.

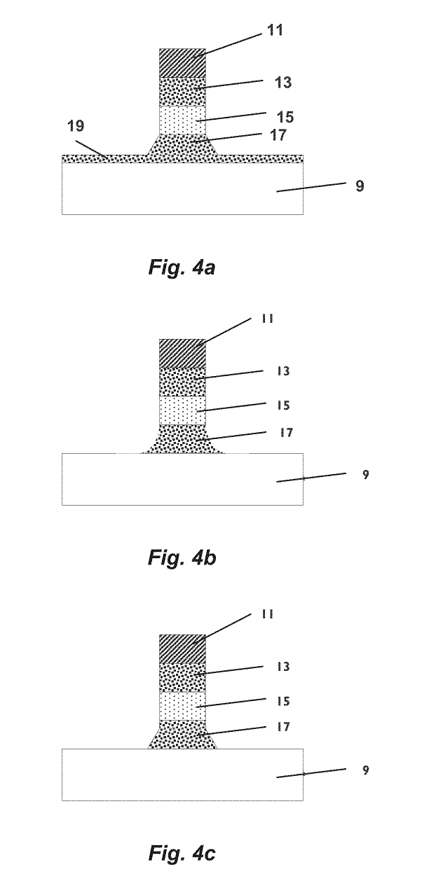

FIG. 4a illustrates an intermediate structure after a lower portion 17 has been formed from the lower layer 7 by etching the lower layer 17 in regions outside the lower layer 7 covered by the mask 11 (and by the intermediate and upper portions 15, 13). The lower portion 17 is formed directly below the intermediate portion 15. The lower portion 17 is vertically aligned with the intermediate portion 15 and the upper portion 13. The lower portion 17 is formed to have, along at least a part of the lower portion 17, a lateral dimension which is gradually increasing along a direction towards the substrate 9. As shown in FIG. 4a, the lower portion 17 may accordingly be formed with a tapering along a vertical direction away from the substrate 9. The lower portion 17 may as shown be formed such that the maximum lateral dimension of the intermediate portion 15 is smaller than the maximum lateral dimension of the lower portion 17. The intermediate portion 15 (as well as the upper portion 13) may as shown be formed with a relatively straight profile. For example, the sidewalls of the intermediate portion 15 (and the upper portion 13) may extend at an angle of 90°±5° with respect to the main surface of the substrate 9.

The upper layer 3 and the intermediate layer 5 may both be etched using a first etching chemistry. The lower layer 7 may be etched using a modified second etching chemistry, or an etching chemistry that is different from the first etching chemistry. Hence, rather than etching the layer stack 1 in a single step or using a constant etching chemistry, the etching of the layer stack 1 may include two steps or using two different etching chemistries.

During the etching, optical emission spectroscopy may be performed to detect gases produced during the etching. For example, an emission spectrum may be measured using a spectrometer of the etching tool. At some point during the etching of the intermediate layer 5, the lower layer 7 is exposed as the etching of the lower layer 7 commences. At this point, due to the different material compositions of the intermediate layer 5 and the lower layer 7, the emission spectrum may change, which change may be used as an indicator or a trigger to end etching with the first etching chemistry and initiate etching with the modified second etching chemistry. In response to detecting that the etch process for forming the intermediate portion 15 has etched through the intermediate layer 5 (e.g., detection of an end-point for the first etching step) and reached the lower layer 7 the etching chemistry may be changed to the (modified) second etching chemistry. In some implementations, the change may be made abruptly or directly in response to detecting the end-point. However, in other implementations, it is also possible to continue etching with the first etching chemistry for some duration before changing to the modified second etching chemistry, e.g., where a tapering is desired along only a part of the lower portion. It yet other implementations, the change in the etching chemistry may be made gradually from the first etching chemistry to the second chemistry, e.g., by gradually changing the flow of component gases. It may further be noted that, under some circumstances, even if the end-point detection is used to directly trigger the change of etching chemistry (for e.g., by stopping the first etching process step, evacuating the reaction and then initiating the second etching process step) it may take a few seconds to obtain a stable gas mixture and/or reach sufficient pressure to obtain plasma ignition for the second etching process step.

The etching process for etching the vertical semiconductor structure may be a dry etching process. The etching process may be performed using a reactive ion etching (RIE) tool, for instance employing an inductively coupled plasma (ICP) or a capacitively coupled plasma (CCP). Each one of the first etching chemistry and the second etching chemistry may be a dry etching chemistry (e.g., a gas plasma), each including a fluoride-including component (F) and a carbon-including component (C) wherein a fluoride-to-carbon-ratio in the second etching chemistry is smaller than a fluoride-to-carbon-ratio in the first etching chemistry. That is, the content of carbon in relation to fluoride may be greater in the second chemistry than in the first etching chemistry.

The first etching chemistry may be a gas mixture of SF₆ as a first component and CF₄ as a second component (optionally supplemented with an inert gas such as N₂ as a third component). The second etching chemistry may also be a gas mixture having the same components, e.g., SF₆ and CF₄ (optionally supplemented with N₂), but having a ratio of SF₆ to CF₄ which is smaller than a ratio of SF₆ to CF₄ of the first etching chemistry. For example, the first etching chemistry may have a ratio of SF₆ to CF₄ in the range of about 1:4 to 1:8. Thereby, the upper portion 13 and the intermediate portion 15 may be formed with a uniform cross section (at least substantially uniform). Alternatively, the first etching chemistry may have a ratio of SF₆ to CF₄ being equal to or greater than about 1:3. Thereby, the upper portion 13 and the intermediate portion 15 may be formed with a gradually decreasing cross section along a vertical direction towards the substrate 9. The second etching chemistry may have a (modified) ratio of SF₆ to CF₄ being equal to or less than about 1:9. Thereby, the lower portion 17 may be formed with a gradually increasing cross section along a vertical direction towards the substrate 9.

Other gas mixtures are possible. For example, CF₄ as the second component of the first etching chemistry and/or the second component of the second etching chemistry may be substituted by another carbon-including component such as CH₂F₂. Accordingly, the first etching chemistry may have a ratio of SF₆ to CH₂F₂ in the range of about 1:0.9 to 1:1.1 to form the upper portion and the intermediate portion 15 with a uniform cross section (at least substantially uniform). Alternatively, the first etching chemistry may have a ratio of SF₆ to CH₂F₂ equal to or greater than about 1:0.8 to form the upper portion 13 and the intermediate portion 15 with a gradually decreasing cross section along a vertical direction towards the substrate 9. The second etching chemistry may also or alternatively have a (modified) ratio of SF₆ to CH₂F₂ equal to or less than about 1:1.2. An SF₆ to CH₂F₂ ratio in this range allows forming of a lower portion 17 with a profile with a comparably uniform slope as shown in FIG. 4a.

Further gas mixtures of the first and the second etching chemistry are also possible. For instance, one of the first and second etching chemistries may include CF₄ and the other of the first and second etching chemistries may include CH₂F₂ as the second component. According to a further alternative, one or both of the first and second etching chemistries may include C₄F₈ as the second component instead of CF₄ or CH₂F₂. Further examples of CHₓF_{y}-based gases include CHF₃ and CH₃F.

Although in FIG. 4a the lower portion 17 is shown to present a rather constant increasing lateral dimension this only represents one option. FIG. 4b shows an alternative wherein the curvature of the lower portion 17 varies along the vertical dimension of the lower portion 17. A varying curvature may be achieved by varying the fluoride-to-carbon ratio during the etching of the lower layer 7. FIG. 4c shows a further alternative wherein the change to the modified second etching chemistry has been delayed compared to the case in FIG. 4a. Hence the etching with the first etching chemistry has progressed by some distance into the lower layer 7.

In some embodiments, as shown in FIG. 4a, the etching process may be stopped before etching completely through the lower layer 7. The remaining thickness portion of the lower layer 7 may form a connection region or bottom electrode layer or region 19 extending under the lower portion 17. A bottom electrode region may, however, also be formed in other ways. For example, a corresponding bottom electrode region may be formed by a heavily doped semiconductor region of the substrate 9, where the doped region extends underneath the lower portion 17.

Depending on the which of the profiles corresponding to FIGS. 4a-4c is to be obtained, the etching may be stopped when or before the substrate 9 is exposed (which for instance may be detected via the emission spectra in the etching tool). In any case, the profiles of the lower portion 17 illustrated in FIGS. 4a-4c can enable varying degrees of increased contact area with respect to an underlying conductive region, such as bottom electrode layer or region 19. Subsequent to completing the etching process, the mask 11 may be removed from the upper portion 13.

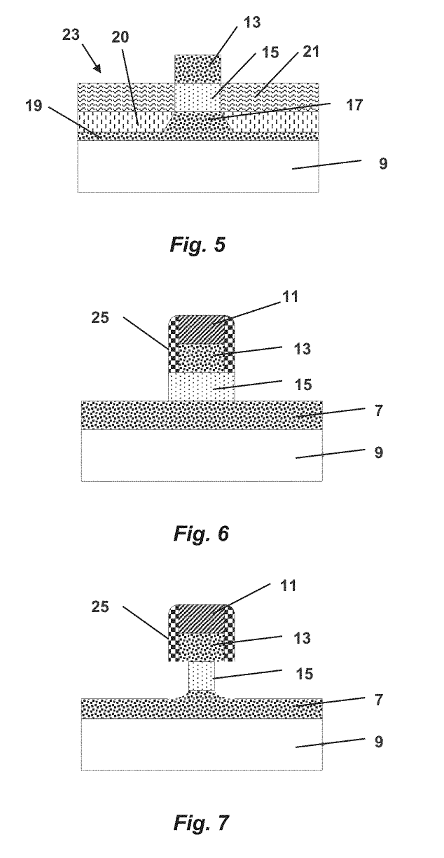

FIG. 5 shows a vertical channel device 23 after further processing the intermediate structure illustrated in FIGS. 4a-4c according to the above-described method. A gate stack 21 has been formed around the intermediate portion 15, enclosing the intermediate portion 15. As described herein, a gate stack 21 includes a gate dielectric and a gate electrode, which are not individually illustrated for clarity. The gate stack 21 may as shown be formed on a bottom insulating layer 20 which has been deposited to embed the lower portion 17 (and cover the bottom electrode region 19 if present, or substrate 9). The bottom insulating layer 20 may accordingly insulate the gate stack 21 from below layers. A channel region of the device 23 may extend vertically in the intermediate portion 15 being enclosed by the gate stack 21. Accordingly, respective source/drain regions of the device 23 may be defined in the upper portion 13 and the lower portion 17, on opposite sides of the channel region. The gate stack 21 may be formed by depositing a gate dielectric layer on the sidewalls of the vertical channel structure and subsequently depositing a conductive gate layer surrounding or embedding the intermediate portion 15. The lateral dimensions of the gate layer may be defined by patterning the gate layer using suitable techniques. A gate stack 21 may also be formed using a replacement metal gate process (RMG), wherein a dummy gate structure may be replaced by a replacement gate structure using conventional processing techniques.

FIGS. 6-7 schematically illustrate additional processing steps according to a variation of the above-described method. With reference to FIG. 6, subsequent to forming the upper portion 13 (e.g., FIG. 2), the etching process may be temporarily halted and a spacer 25 may be formed on the sidewalls of the upper portion 13 (and of the mask 11). The spacer 25 may be formed by depositing a conformal spacer layer on the structure and thereafter vertically etching the conformal spacer layer to remove the conformal spacer layer from horizontally oriented surfaces, thereby leaving the spacer 25 on the sidewalls. The spacers may be formed of a dielectric material, such as Si₃N₄, SiO₂, SiOC, SiCO, SiON, Al₂O₃ or HfO₂. However a metal-based spacer material is also possible such as AlN or TiN.

Following forming of the spacer 25, the etching process may be resumed wherein etching of the intermediate layer 5 may be performed to form the intermediate portion 15. Subsequently, the lower layer 7 may be etched to form the lower portion 17, as described above. During the etching of the lower layer 7 to form the lower portion 17, the spacer 25 may mask to prevent or counteract lateral etching of the upper portion 13. Following the etching of the layer stack 1, the spacer 25 may be removed and the method may proceed as described in connection with FIG. 5 above. Thus, in some embodiments, the resulting vertical channel device may have an intermediate portion 13 that is relatively wider than the upper portion 13.

Alternatively, an optional thinning of the intermediate portion 15 may be performed as illustrated in FIG. 7. The intermediate portion 15 may be thinned by oxidation or by wet etching, for instance a diluted HF-based etch. During the thinning, the spacer 25 may counteract thinning of the upper portion 13 (although as shown a lowermost surface of the upper layer 13 may still be slightly affected by the thinning process). In FIG. 7 the thinning is shown to be performed prior to forming the lower portion 17 however it is also possible to perform the thinning subsequent to forming the lower portion 17 provided some loss of cross-sectional dimension of the lower portion 17 is acceptable.

Thus, referring to FIGS. 6 and 7, in some embodiments, the vertical channel device 23 has a discontinuity in width at an interface between the upper portion 13 and the intermediate portion 15.

In the above, the disclosed technology has mainly been described with reference to a limited number of examples. However, as is readily appreciated by a person skilled in the art, other examples than the ones disclosed above are equally possible within the scope of the inventive concept, as defined by the appended claims.

For instance, although in the above a same “first” etching chemistry is used for etching the upper and the intermediate layers 3, 5 it is also possible to use different etching chemistries during etching of the upper and the intermediate layers 3, 5, i.e. a first etching chemistry may be used for etching the upper layer 3, a second etching chemistry (different from the first) may be used for etching the intermediate layer 5 and a third etching chemistry (different from the second and the first etching chemistries) may be used for etching the lower layer 7 in the manner described above. For instance, the first etching chemistry may be chosen to form the upper portion 13 with a gradually decreasing cross section (in a direction towards the substrate 9) while the second etching chemistry may be chosen to form the intermediate portion 15 with a uniform cross section. The change from the first etching chemistry to the second etching chemistry may be performed in response to detecting (e.g., via the emission spectra) that the etching of the upper layer 3 has reached the intermediate layer 5.

What is claimed is:

1. A method of forming a vertical channel device, the method comprising:
forming a vertical semiconductor structure including an upper portion, an intermediate portion and a lower portion, by etching a semiconductor layer stack arranged on a substrate, the semiconductor layer stack including an upper semiconductor layer, an intermediate semiconductor layer and a lower semiconductor layer, wherein the intermediate semiconductor layer is formed of a material different from a material of the lower semiconductor layer and different from a material of the upper semiconductor layer,
wherein the forming of the vertical semiconductor structure comprises:
etching the upper semiconductor layer to form the upper portion and the intermediate semiconductor layer to form the intermediate portion,
detecting whether the etching has reached the lower semiconductor layer, and
in response to detecting that the etching has reached the lower semiconductor layer, changing to a modified etching chemistry different from an etching chemistry used during the etching of the intermediate semiconductor layer, and etching the lower semiconductor layer using the modified etching chemistry to form the lower portion, wherein the modified etching chemistry is such that the lower portion is formed to present, along at least a part of the lower portion, a lateral dimension gradually increasing along a direction towards the substrate,
and the method further comprising:
forming a gate stack extending vertically along the intermediate portion to define a channel region of the vertical channel device.

2. The method according to claim 1, wherein the etching chemistry and the modified etching chemistry are dry etching chemistries each including a fluoride-including component and a carbon-including component, wherein a fluoride-to-carbon-ratio in the modified etching chemistry is smaller than a fluoride-to-carbon-ratio in the etching chemistry.

3. The method according to claim 2, wherein the fluoride-including component comprises SF₆ and the carbon-including component is a fluorocarbon.

4. The method according to claim 3, wherein the fluorocarbon includes a gas selected from the group consisting of CF₄, C₂F₄, CHₓF_{y}, CH₂F₂ and a combination thereof.

5. The method according to claim 3, wherein the modified etching chemistry comprises SF₆ and CH₂F₂ that are present at a SF₆:CH₂F₂ ratio that is equal to or less than 1:1.2.

6. The method according to claim 1, wherein a maximum lateral dimension of the intermediate portion is smaller than a maximum of the lateral dimension of the lower portion.

7. The method according to claim 1, wherein the lower semiconductor layer has a Ge-content that is greater than a Ge-content of the intermediate semiconductor layer.

8. The method according to claim 7, wherein the upper semiconductor layer has a Ge-content that is greater than the Ge-content of the intermediate semiconductor layer.

9. The method according to claim 8, wherein the lower semiconductor layer includes Si and Ge, the intermediate layer includes Si, and the upper semiconductor layer includes Si and Ge.

10. The method according to claim 1, further comprising:
subsequent to forming the upper portion, and prior to forming the intermediate portion, forming a spacer layer on sidewalls of the upper portion, and
subsequent to forming the spacer layer, etching the intermediate semiconductor layer to form the intermediate portion.

11. The method according to claim 10, further comprising:
subsequent to forming the intermediate portion, reducing a lateral dimension of the intermediate portion by etching the intermediate portion, wherein the spacer layer counteracts etching of the upper portion.

12. The method according to claim 10, further comprising:
subsequent to forming the intermediate portion, reducing a lateral dimension of the intermediate portion by oxidizing the intermediate portion, wherein the spacer layer counteracts oxidation of the upper portion.

13. The method according to claim 12, wherein a material forming the intermediate semiconductor layer has a greater oxidation rate than a material forming the lower semiconductor layer.

14. The method according to claim 1, wherein forming the gate stack includes forming a gate conductor enclosing the intermediate portion.

15. A vertical channel device, comprising:
a substrate;
a vertical semiconductor structure arranged on the substrate and including an upper portion, an intermediate portion and a lower portion, wherein the intermediate portion is formed of a material different from a material of the lower portion and a material of the upper portion,
wherein the lower portion includes at least a portion in which a lateral dimension gradually increases towards the substrate; and
a gate stack extending vertically along the intermediate portion to define a channel region of the vertical channel device.

16. The vertical channel device of claim 15, wherein the gate stack surrounds the intermediate portion such that the vertical channel device is configured as a gate-all-around field effect transistor.

17. The vertical channel device of claim 15, wherein each of the upper portion and the lower portion comprises Ge, and wherein the intermediate portion has one or both of Si and Ge, and wherein the intermediate portion has Ge at a lower concentration relative to the upper portion and the lower portion.

18. The vertical channel device of claim 16, wherein one of the upper portion and the lower portion serves as one of a source or a drain, and wherein the other of the upper portion and the lower portion serves as the other of the source or the drain.

19. The vertical channel device of claim 18, wherein the lower portion is formed on a bottom electrode layer formed of the same material as the lower portion, and wherein the gate stack extends laterally to overlap the bottom electrode layer.

20. The vertical channel device of claim 18, wherein the vertical channel device has a discontinuity in width at an interface between the upper portion and the intermediate portion.
